(19) United States
(12) Patent Application Publication
(10) Pub. No.: US 2015/0173197 A1
(43) Pub. Date: Jun. 18, 2015

(54) PRINTED CIRCUIT BOARD HAVING INDUCTOR EMBEDDED THEREIN AND MANUFACTURING METHOD THEREOF

(71) Applicant: SAMSUNG ELECTRO-MECHANICS CO., LTD., Suwon-Si (KR)

(72) Inventors: Suk Hyeon Cho, Suwon-Si (KR); Yong Sam Lee, Suwon-Si (KR); Jin O Yoo, Suwon-Si (KR)

(73) Assignee: SAMSUNG ELECTRO-MECHANICS CO., LTD.

(21) Appl. No.: 14/453,289

(22) Filed: Aug. 6, 2014

(30) Foreign Application Priority Data
Dec. 13, 2013 (KR) 10-2013-0155272

(51) Int. Cl. H05K 1/18; H05K 3/10; H05K 3/00

(52) U.S. Cl. CPC H05K 1/185; H05K 3/0047; H05K 3/107

(57) ABSTRACT

A printed circuit board having an inductor embedded therein may include a conductive coil part embedded in an insulating layer; and a magnetic material part integrally formed so as to enclose a vicinity of the conductive coil part. In the printed circuit board having the inductor embedded therein, a gap between coils is narrowed and coils having a high height and a narrow width are formed, whereby resistance may be decreased and a higher inductance value may be implemented in a narrow area.

### CROSS-REFERENCE TO RELATED APPLICATION

This application claims the benefit of Korean Patent Application No. 10-2013-0155272 filed on Dec. 13, 2013, with the Korean Intellectual Property Office, the disclosure of which is incorporated herein by reference.

### BACKGROUND

The present disclosure relates to a printed circuit board having an inductor embedded therein, and a manufacturing method thereof.

Passive devices generally used in electric and electronic circuits mainly include resistors, capacitors, and inductors. Among such devices, capacitors and inductors are the most basic devices capable of storing and discharging energy.

Recently, in accordance with the development of information technology (IT), the miniaturization, lightening and thinning of electronic apparatuses have progressed, and passive devices used in the electronic apparatuses have also been further miniaturized in accordance with the development of manufacturing technologies and device designs. Particularly, the miniaturization of capacitors and inductors, as described above, has become an important criterion in determining product size.

Further, in accordance with the development of semiconductor technology, the miniaturization of semiconductors has progressed, and as it is expected that nano-processing technology will be commercialized in the future, power signal transfer characteristics in a board have come to prominence. Therefore, demand for a technology allowing for the embedding of a capacitor or an inductor in a board has increased.

According to the related art, an inductor component has been implemented in a scheme of forming plating resists on both surfaces of an insulating material, respectively, selectively removing the plating resists, and forming coil turns in portions in which the plating resists are removed by plating as in a general circuit forming method.

Here, in order to lower resistance of the coil turns, a conductive area should be increased. However, when coils are formed using turns formed to be low and wide, as coil turn amounts are gradually increased, there is a problem that the lengths of turns may be increased in an outer portion of the coil circuit.

Therefore, a scheme capable of decreasing resistance and increasing inductance is to form coil turns having a high height and a narrow width, while decreasing a gap between the coil turns to be as narrow as possible.

However, in the case of forming the coil turns using the plating resist, in order to form the plating resist to have a high height and to maintain a form thereof, the plating resist should have a predetermined width or more. When the plating resist is formed to have a high height and a narrow width, due to a shape thereof, the plating resist may easily collapse or be damaged, such that the plating resist may not adequately perform a role of a plating resist between turns.

Therefore, in the case of forming the coil turns on the insulating material using the plating resist, there is a limitation in narrowing a gap between the coil turns and forming the coil turns having a high height and a narrow width.

### RELATED ART DOCUMENT

(Patent Document 1) Japanese Patent Laid-Open Publication No. 2002-324962

### SUMMARY

An exemplary embodiment in the present disclosure may provide a printed circuit board in which an inductor appropriate for an electronic apparatus that has been miniaturized and had a high degree of complexity implemented therein by narrowing a gap between coils and forming coils having a high height and a narrow width to implement a higher inductance value in a narrow area is embedded, and a manufacturing method thereof.

According to an exemplary embodiment in the present disclosure, a printed circuit board having an inductor embedded therein may include: a conductive coil part embedded in an insulating layer; and a magnetic material part integrally formed so as to enclose a vicinity of the conductive coil part.

The conductive coil part may include an upper conductive coil part embedded from an upper surface of the insulating layer and a lower conductive coil part embedded from a lower surface of the insulating layer.

The upper conductive coil part and the lower conductive coil part may be formed on the upper and lower surfaces of the insulating layer, respectively, so as to alternate with each other.

The upper conductive coil part and the lower conductive coil part may be electrically connected to each other through a connection part formed in the insulating layer.

Widths of respective coils of the conductive coil part may be narrowed from a surface of the insulating layer toward an internal portion thereof.

A gap between coils of the conductive coil part may be 10 μm or less.

The conductive coil part may penetrate through the insulating layer.

The magnetic material part may be formed by filling a magnetic material in a through-hole formed in the vicinity of the conductive coil part.

The printed circuit board having an inductor embedded therein may further include an insulating layer formed between the conductive coil part and the magnetic material part.

According to an exemplary embodiment in the present disclosure, a manufacturing method of a printed circuit board having an inductor embedded therein may include: forming concave parts in at least one surface of an insulating layer; forming a conductive coil part embedded in the insulating layer by performing plating on internal portions of the concave parts; forming a through-hole in a vicinity of the conductive coil part; and forming an integral magnetic material part enclosing the vicinity of the conductive coil part by filling a magnetic material in the through-hole.

The concave parts may be formed in upper and lower surfaces of the insulating layer, and upper and lower conductive coil parts embedded from the upper and lower surfaces of the insulating layer, respectively, may be formed.

The upper conductive coil part and the lower conductive coil part may be formed on the upper and lower surfaces of the insulating layer, respectively, so as to alternate with each other.

The manufacturing method may further include forming a connection part in the insulating layer, the connection part connecting the upper conductive coil part and the lower conductive coil part to each other.

Widths of respective coils of the conductive coil part may be narrowed from a surface of the insulating layer toward an internal portion thereof.

The concave part may have a conical shape, a trapezoidal shape, or a semi-elliptical shape.

A copper foil layer may be formed on at least one surface of the insulating layer, and the concave part penetrating through the insulating layer may be formed.

A gap between coils of the conductive coil part may be 10 μm or less.

According to an exemplary embodiment in the present disclosure, a printed circuit board having an inductor embedded therein may include: a core layer; and a conductive coil part embedded so that a surface thereof is exposed to the core layer.

The printed circuit board having an inductor embedded therein may further include an insulating layer formed on the exposed surface of the conductive coil part.

The printed circuit board having an inductor embedded therein may further include a magnetic material part formed on the insulating layer.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view of a printed circuit board having an inductor embedded therein according to an exemplary embodiment in the present disclosure;

FIG. 2 is a plan view of a coil part of the printed circuit board having an inductor embedded therein according to an exemplary embodiment in the present disclosure;

FIG. 3 is a cross-sectional view taken along line A-A′ of FIG. 2;

FIG. 4 is a cross-sectional view taken along line B-B′ of FIG. 2;

FIG. 5 is an enlarged view of part C of FIG. 2;

FIG. 6 is a plan view of a coil part of the printed circuit board having an inductor embedded therein according to an exemplary embodiment in the present disclosure;

FIG. 7 is a cross-sectional view taken along line A-A′ of FIG. 6;

FIG. 8 is a cross-sectional view of a trapezoidal coil part of the printed circuit board having an inductor embedded therein according to an exemplary embodiment in the present disclosure;

FIG. 9 is a cross-sectional view of a semi-elliptical coil part of the printed circuit board having an inductor embedded therein according to an exemplary embodiment in the present disclosure;

FIG. 10 is a cross-sectional view of a penetration shaped coil part of the printed circuit board having an inductor embedded therein according to an exemplary embodiment in the present disclosure;

FIG. 11 is a flow chart showing a manufacturing method of a printed circuit board having an inductor embedded therein according to an exemplary embodiment in the present disclosure;

FIGS. 12A through 12D are views schematically describing the manufacturing method of a printed circuit board having an inductor embedded therein according to an exemplary embodiment in the present disclosure; and

FIGS. 13A and 13B are views schematically showing a manufacturing process of a coil part penetrating through an insulating layer of the printed circuit board having an inductor embedded therein according to an exemplary embodiment in the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

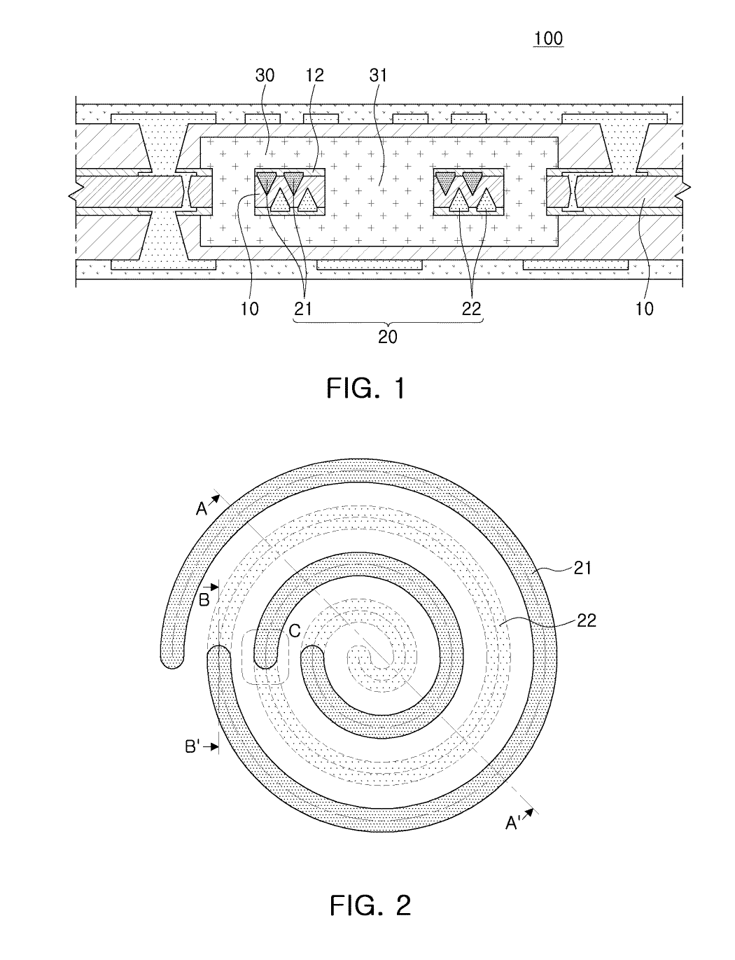

FIG. 1 is a cross-sectional view of a printed circuit board having an inductor embedded therein according to an exemplary embodiment of the present disclosure; and FIG. 2 is a plan view of a coil part of the printed circuit board having an inductor embedded therein according to an exemplary embodiment of the present disclosure.

Referring to FIGS. 1 and 2, a printed circuit board 100 having an inductor embedded therein according to an exemplary embodiment of the present disclosure may include a conductive coil part 20 embedded in an insulating layer (core layer) 10 forming a core and a magnetic material part 30 integrally formed so as to enclose a vicinity of the conductive coil part 20.

Insulating layers 12 may be stacked on upper and lower portion of the conductive coil part 20. Since insulating layers 10 are formed on side portions of the conductive coil part 20 and the insulating layers 12 are formed on the upper and lower portions of the conductive coil part 20, the conductive coil part 20 may not directly contact the magnetic material part 30.

The printed circuit board 100 having an inductor embedded therein may include a terminal electrode, a surface wiring pattern such as a connecting pad, or the like, an internal wiring pattern, a chip state electronic component, a lead form electronic component, an electronic component such as an integrated circuit (IC) chip, or the like, a via electrode electrically connecting them to each other, and the like, in addition to the inductor implemented so as to include the conductive coil part 20 and the magnetic material part 30.

The conductive coil part 20 may be formed in a form in which it is embedded in the insulating layer 10 by forming a concave part in at least one surface of the insulating layer 10 and performing plating on an internal portion of the concave part.

The conductive coil part 20 may have a spiral coil structure and may be formed of a metal having excellent electrical conductivity, for example, silver (Ag), palladium (Pd), aluminum (Al), nickel (Ni), titanium (Ti), gold (Au), copper (Cu), platinum (Pt), an alloy thereof, or the like.

The conductive coil part 20 may include an upper conductive coil part 21 embedded from an upper surface of the insulating layer 10 and a lower conductive coil part 22 embedded from a lower surface of the insulating layer 10.

The upper conductive coil part 21 and the lower conductive coil part 22 are not formed at positions of the upper and lower surfaces of the insulating layer 10 facing each other, but may be formed so as to alternate with each other.

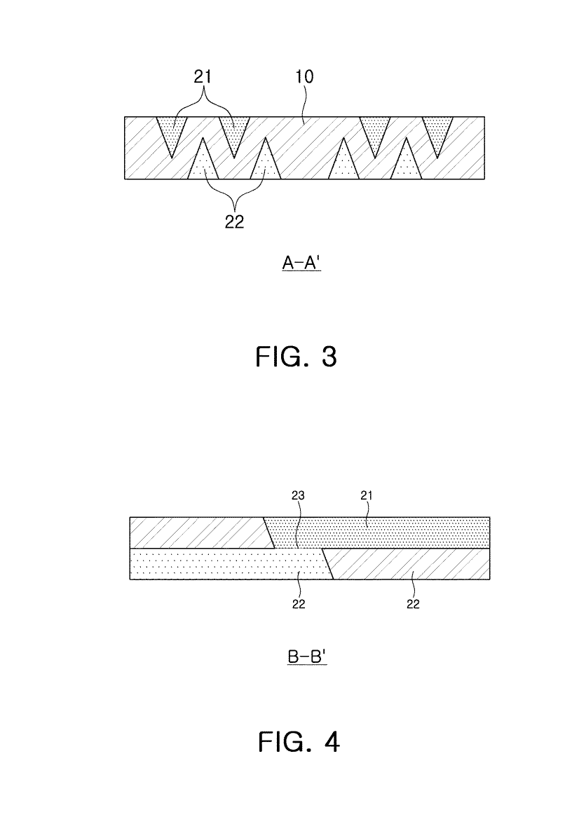

FIG. 3 is a cross-sectional view taken along line A-A′ of FIG. 2. Referring to FIG. 3, it may be appreciated that the upper conductive coil part 21 and the lower conductive coil part 22 are not formed at the positions of the upper and lower surfaces of the insulating layer 10 facing each other, but are formed so as to alternate with each other, such that the upper conductive coil part 21 and the lower conductive coil part 22 are alternately formed so as to neighbor to each other when viewed on a cross section. Therefore, a coil gap between layers may be decreased as compared with the case in which the coil parts are formed on both surfaces of an insulating material.

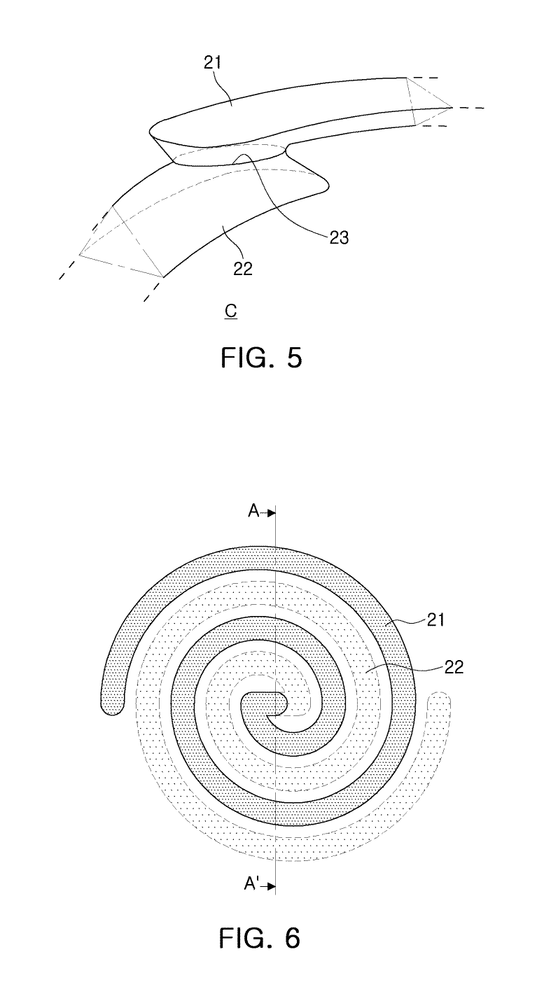

FIG. 4 is a cross-sectional view taken along line B-B′ of FIG. 2; and FIG. 5 is an enlarged view of part C of FIG. 2.

Referring to FIGS. 4 and 5, the upper conductive coil part 21 and the lower conductive coil part 22 may be electrically connected to each other through a connection part 23 formed in the insulating layer 10. The upper conductive coil part 21 and the lower conductive coil part 22 may be connected to each other through at least one connection part 23.

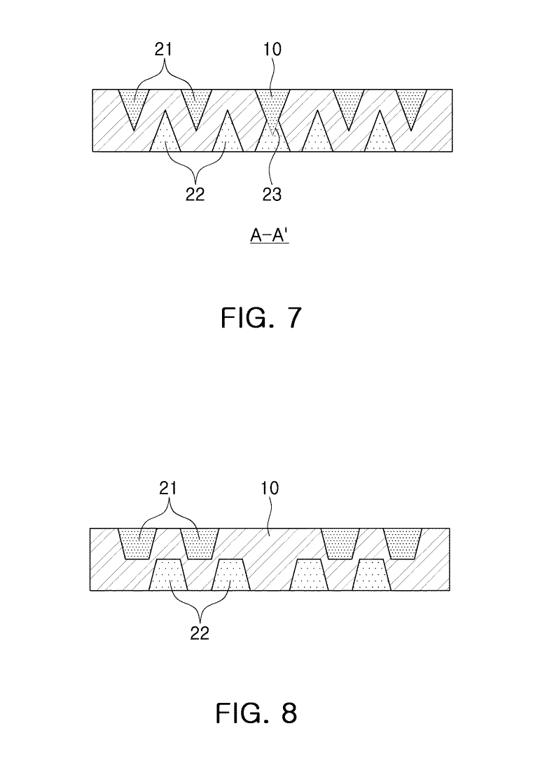

FIG. 6 is a plan view of a coil part of the printed circuit board having an inductor embedded therein according to another exemplary embodiment of the present disclosure; and FIG. 7 is a cross-sectional view taken along line A-A′ of FIG. 6.

Referring to FIGS. 6 and 7, an upper conductive coil part 21 having a spiral shape may be formed on an upper surface of an insulating layer 10, a lower conductive coil part 22 having a spiral shape may be formed on a lower surface of the insulating layer 10 so as not to face a region in which the upper conductive coil part 21 is formed, and a connection part 23 electrically connecting the upper conductive coil part 21 and the lower conductive coil part 22 to each other may be formed at the center of a conductive coil part having a spiral shape.

The conductive coil part 20 may have a shape in which a width of a coil is narrowed from a surface of the insulating layer 10 toward an internal portion of the insulating layer 10.

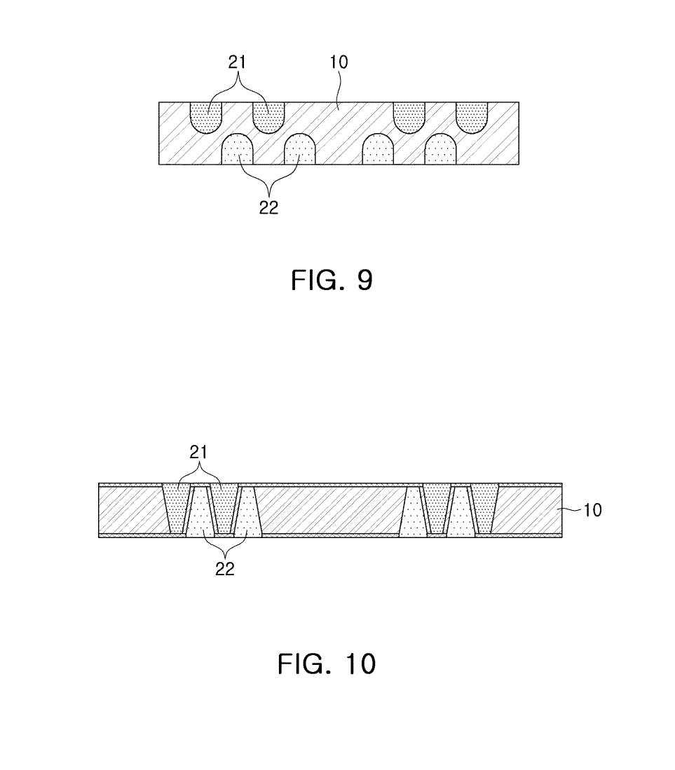

A shape of a coil is not particularly limited, but may be, for example, a conical shape in which a width of the coil are narrowed from the surface of the insulating layer 10 toward the internal portion of the insulating layer 10, as shown in FIGS. 1, 3, and 7, a trapezoidal shape and a semi-elliptical shape as shown in FIGS. 8 and 9, or the like.

Meanwhile, the conductive coil part 20 may penetrate through the insulating layer 10.

Referring to FIG. 10, the conductive coil part 20 penetrating through the insulating layer 10 is formed using a copper foil layer stacked on one surface of the insulating layer 10 as a stopper, whereby each coil may be constantly formed at a depth that is the same as a thickness of the insulating layer 10.

A gap between the coils of the conductive coil part 20 may be 10 μm or less. The gap between the coils may indicate a gap between neighboring coils on one surface of the insulating layer 10. The conductive coil part 20 embedded in the insulating layer 10 is formed without using a plating resist, whereby the gap between the coils may be decreased as small as possible. Therefore, resistance may be decreased, and high inductance may be implemented in a narrow area. More preferably, the gap between the coils of the conductive coil part 20 may be 5 μm or less.

The magnetic material part 30 may be formed by filling a magnetic material in a through-hole formed in the vicinity of the conductive coil part 20.

An integral magnetic material part 30 having a form in which it completely enclose the conductive coil part 20 may be formed by forming the through-hole, which is a space to be filled with the magnetic material, in advance and filling the magnetic material in the through-hole.

A magnetic material core part 31 may be formed by forming a through-hole in a central portion of the conductive coil part 20 and filling a magnetic material in the through-hole. The magnetic material core part 31 may be formed at the center of the conductive coil part 20, such that an inductance value may be improved.

The magnetic material part 30 may contain a material having magnetic characteristics. For example, the magnetic material part 30 may be formed by filling a ferrite material or a metal based soft magnetic material. Mn—Zn based ferrite, Ni—Zn based ferrite, Ni—Zn—Cu based ferrite, Mn—Mg based ferrite, Ba based ferrite, Li based ferrite, or the like, may be used as the ferrite, and a Fe—Si—B—Cr based amorphous metal powder material may be used as the metal based soft magnetic material. However, the present disclosure is not limited thereto.

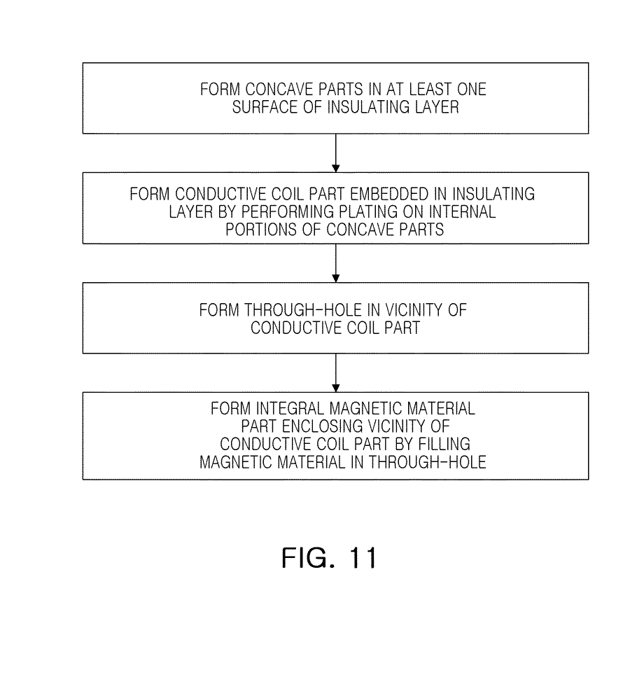

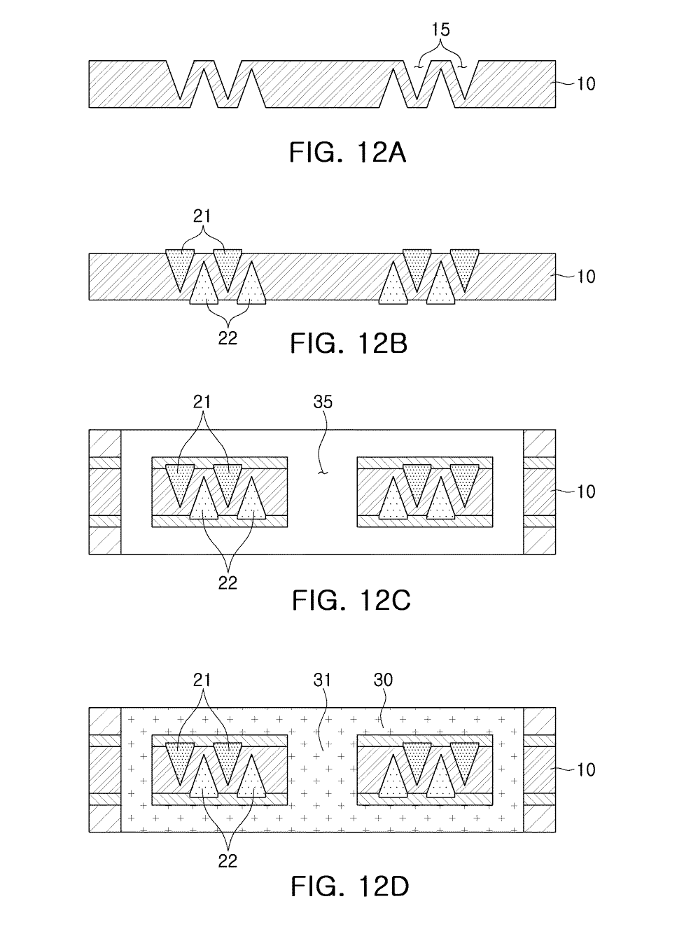

FIG. 11 is a flow chart showing a manufacturing method of a printed circuit board having an inductor embedded therein according to an exemplary embodiment of the present disclosure; and FIGS. 12A through 12D are views schematically describing the manufacturing method of a printed circuit board having an inductor embedded therein according to an exemplary embodiment of the present disclosure.

Referring to FIGS. 11 through 12D, concave parts 15 may be formed in at least one surface of the insulating layer 10.

The concave part 15 may be formed by performing drilling, laser processing, sand blasting, punching, or the like, on the insulating layer 10.

The concave part 15 may have a shape in which a width thereof are narrowed from a surface of the insulating layer 10 toward an internal portion of the insulating layer 10. A shape of the concave part 15 is not particularly limited, but may be, for example, a conical shape, a trapezoidal shape, a semi-elliptical shape, or the like.

Meanwhile, the concave part 15 may penetrate through the insulating layer 10.

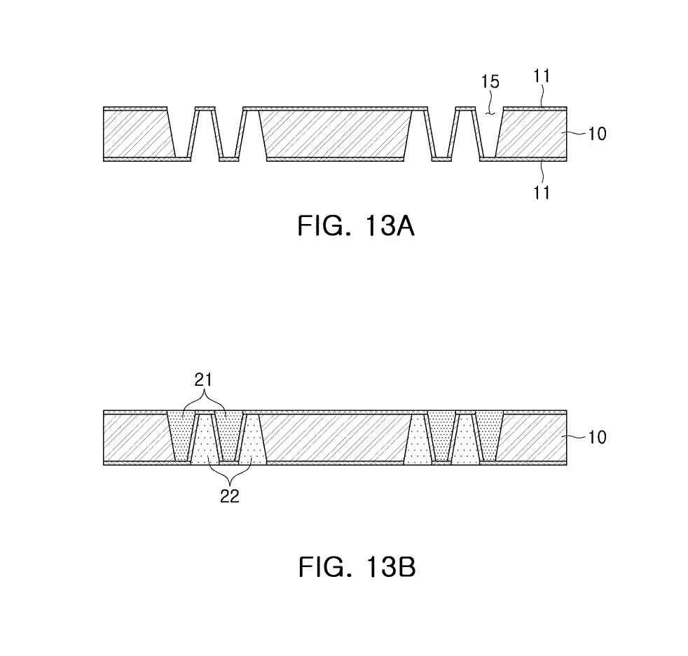

FIGS. 13A and 13B are views schematically showing a manufacturing process of a coil part penetrating through an insulating layer of the printed circuit board having an inductor embedded therein according to an exemplary embodiment of the present disclosure.

Referring to FIGS. 13A and 13B, the concave parts 15 penetrating through the insulating layer 10 may be formed using the copper foil layer 11 stacked on one surface of the insulating layer 10 as a stopper. The concave parts 15 penetrating through the insulating layer 10 are formed using the copper foil layer 11 as the stopper, whereby each coil that is to be formed later by performing plating on an internal portion of the concave part 15 may be constantly formed at a depth that is the same as a thickness of the insulating layer 10.

Next, the conductive coil part 20 embedded in the insulating layer 10 may be formed by performing the plating on the internal portions of the concave parts 15.

The conductive coil part 20 may be formed by an electroplating method, or the like, and be formed of a metal having excellent electrical conductivity, for example, silver (Ag), palladium (Pd), aluminum (Al), nickel (Ni), titanium (Ti), gold (Au), copper (Cu), platinum (Pt), an alloy thereof, or the like.

The concave parts 15 may be formed on both surfaces of the insulating layer 10, respectively, and plating may be performed to form the upper conductive coil part 21 and the lower conductive coil part 22.

The upper conductive coil part 21 and the lower conductive coil part 22 are not formed at positions of the upper and lower surfaces of the insulating layer 10 facing each other, but may be formed so as to alternate with each other.

The connection part 23 may be formed in a penetration region of the insulating layer 10, which is a portion of the insulating layer 10, such that the upper conductive coil part 21 and the lower conductive coil part 22 may be electrically connected to each other through the connection part 23.

The conductive coil part 20 formed by performing the plating on the concave parts 15 having a width that are narrowed from the surface of the insulating layer 10 toward the internal portion of the insulating layer 10 may have a shape in which Widths of respective coils of thereof are narrowed from the surface of the insulating layer 10 toward the internal portion of the insulating layer 10.

The conductive coil part 20 may be formed so that a gap between the coils thereof may be 10 μm or less. The concave part 15 is formed in the insulating layer 10 and the plating is performed to form the conductive coil part 20 embedded in the insulating layer 10 without using a plating resist, whereby the gap between the coils may be decreased as small as possible. Therefore, resistance may be decreased, and high inductance may be implemented in a narrow area.

Next, the through-hole 35, which is a space to be filled with the magnetic material, may be formed in the vicinity of the conductive coil part 20.

The through-hole 35 may be formed by performing drilling, laser processing, sand blasting, punching, or the like, and may also be formed in a central portion of the conductive coil part 20 in order to increase an area in which the magnetic material is filled to improve an inductance value.

Next, the magnetic material may be filled in the through-hole 35 to form the integral magnetic material part 30 enclosing a vicinity of the conductive coil part 20.

The integral magnetic material part 30 having a form in which it completely enclose the conductive coil part 20 may be formed by forming the through-hole 35, which is the space to be filled with the magnetic material, in advance and filling the magnetic material in the through-hole 35.

The magnetic material part 30 may contain a material having magnetic characteristics. For example, the magnetic material part 30 may be formed by filling a ferrite material or a metal based soft magnetic material. Mn—Zn based ferrite, Ni—Zn based ferrite, Ni—Zn—Cu based ferrite, Mn—Mg based ferrite, Ba based ferrite, Li based ferrite, or the like, may be used as the ferrite, and a Fe—Si—B—Cr based amorphous metal powder material may be used as the metal based soft magnetic material. However, the present disclosure is not limited thereto.

In the printed circuit board having an inductor embedded therein manufactured as described above, the gap between the coils may be narrowed, the coils having a high height and a narrow width may be formed, and the magnetic material may completely enclose the coils, such that efficiency such as inductance may be significantly improved.

As set forth above, in the printed circuit board having an inductor embedded therein according to exemplary embodiments of the present disclosure, the gap between the coils is narrowed and the coils having a high height and a narrow width are formed, whereby resistance may be decreased and a higher inductance value may be implemented in a narrow area.

While exemplary embodiments have been shown and described above, it will be apparent to those skilled in the art that modifications and variations could be made without departing from the spirit and scope of the present disclosure as defined by the appended claims.

What is claimed is:

1. A printed circuit board having an inductor embedded therein, comprising:
a conductive coil part embedded in an insulating layer; and
a magnetic material part enclosing a vicinity of the conductive coil part.

2. The printed circuit board having an inductor embedded therein of claim 1, wherein the conductive coil part includes an upper conductive coil part embedded from an upper surface of the insulating layer and a lower conductive coil part embedded from a lower surface of the insulating layer.

3. The printed circuit board having an inductor embedded therein of claim 2, wherein the upper conductive coil part and the lower conductive coil part are formed on the upper and lower surfaces of the insulating layer, respectively, so as to alternate with each other.

4. The printed circuit board having an inductor embedded therein of claim 2, wherein the upper conductive coil part and the lower conductive coil part are electrically connected to each other through a connection part formed in the insulating layer.

5. The printed circuit board having an inductor embedded therein of claim 1, wherein Widths of respective coils of the conductive coil part are narrowed from a surface of the insulating layer toward an internal portion thereof.

6. The printed circuit board having an inductor embedded therein of claim 1, wherein a gap between coils of the conductive coil part is 10 μm or less.

7. The printed circuit board having an inductor embedded therein of claim 1, wherein the conductive coil part penetrates through the insulating layer.

8. The printed circuit board having an inductor embedded therein of claim 1, wherein the magnetic material part is formed by filling a magnetic material in a through-hole formed in the vicinity of the conductive coil part.

9. The printed circuit board having an inductor embedded therein of claim 1, further comprising an insulating layer formed between the conductive coil part and the magnetic material part.

10. A manufacturing method of a printed circuit board having an inductor embedded therein, comprising:
forming concave parts in at least one surface of an insulating layer;
forming a conductive coil part embedded in the insulating layer by performing plating on internal portions of the concave parts;
forming a through-hole in a vicinity of the conductive coil part; and
forming an integral magnetic material part enclosing the vicinity of the conductive coil part by filling a magnetic material in the through-hole.

11. The manufacturing method of claim 10, wherein the concave parts are formed in upper and lower surfaces of the insulating layer, and upper and lower conductive coil parts embedded from the upper and lower surfaces of the insulating layer, respectively, are formed.

12. The manufacturing method of claim 11, wherein the upper conductive coil part and the lower conductive coil part are formed on the upper and lower surfaces of the insulating layer, respectively, so as to alternate with each other.

13. The manufacturing method of claim 11, further comprising forming a connection part in the insulating layer, the connection part connecting the upper conductive coil part and the lower conductive coil part to each other.

14. The manufacturing method of claim 10, wherein Widths of respective coils of the conductive coil part are narrowed from a surface of the insulating layer toward an internal portion thereof.

15. The manufacturing method of claim 10, wherein the concave part has a conical shape, a trapezoidal shape, or a semi-elliptical shape.

16. The manufacturing method of claim 10, wherein a copper foil layer is formed on at least one surface of the insulating layer, and the concave part penetrating through the insulating layer is formed.

17. The manufacturing method of claim 10, wherein a gap between coils of the conductive coil part is 10 μm or less.

18. A printed circuit board having an inductor embedded therein, comprising:
a core layer; and
a conductive coil part embedded so that a surface thereof is exposed to the core layer.

19. The printed circuit board having an inductor embedded therein of claim 18, further comprising an insulating layer formed on the exposed surface of the conductive coil part.

20. The printed circuit board having an inductor embedded therein of claim 19, further comprising a magnetic material part formed on the insulating layer.
